(19) United States
(12) Patent Application Publication
(10) Pub. No.: US 2017/0181301 A1
(43) Pub. Date: Jun. 22, 2017

(54) ELECTRONIC STORAGE AND TRANSMISSION DEVICE

(71) Applicant: PhotoFast Co. Ltd., Taipei City (TW)

(72) Inventor: Warren WANG, Taipei City (TW)

(21) Appl. No.: 15/386,451

(22) Filed: Dec. 21, 2016

(30) Foreign Application Priority Data
Dec. 22, 2015 (TW) 104220531

(51) Int. Cl. H05K 5/02; H01R 24/28; H01R 24/60

(52) U.S. Cl. CPC H05K 5/0278; H01R 24/60; H01R 24/28; H05K 5/0217; H05K 5/0247; H01R 2107/00

(57) ABSTRACT

A holding structure of an electronic storage and transmission device of the present invention has a storage and transmission body and a holding base. The storage and transmission body connects to a transmission connector through a connecting wire. The holding base has a receiving slot formed on a top surface of the storage and transmission body, and the transmission connector can be fixed in the receiving slot. Due to only an end portion of the connecting wire fixed on the holding base, the connecting wire can be fully expanded, operation freedom and connection angle are thereby increased; and by disposing the holding base, the transmission connector can be directly fixed in the holding base, so that a folded volume of the electronic storage and transmission device is reduced. Additionally, the electronic storage and transmission device can have functions of storing data and charging electronic devices at the same time.

### CROSS-REFERENCE TO RELATED APPLICATION

This application claims the priority of Taiwanese patent application No. 104220531, filed on Dec. 22, 2015, which is incorporated herewith by reference.

### FIELD OF THE INVENTION

The present invention relates to an electronic storage and transmission device, especially to an electronic storage and transmission having a holding base.

### BACKGROUND OF THE INVENTION

1. Field of the Invention

The line-type flash drive is an electronic storage and transmission device, which can not only be a memory storage device easy to carry, but also a charging and data transmitting media for electronic products such as smartphones or tablets.

2. The Prior Arts

Please refer to FIG. 5. The line-type flash drive of current technology has a storage and transmission body 40, a connecting wire 50 and a transmission connector 60. The storage and transmission body 40 is a flash drive, so it can be as a memory storage device, and an end portion of the storage and transmission body 40 electrically connects to the transmission connector 60 through the connecting wire 50, and the transmission connector 60 is used for connecting to electronic products, so as to achieve functions of charging the electronic products and transmitting data.

When use of the line-type flash drive is finished and fold thereof is desirable, a user folds and fixes the connecting wire 50 by a wire constraint member 70. The wire constraint member 70 has a first fixing slot 71, an open slot 72 and a second fixing slot 73, the first fixing slot 72 and the second fixing slot 73 are through formed in the wire constraint member 70; the open slot 72 is formed at a side edge of the wire constraint member 70, and communicates with the second fixing slot 73. The connecting wire 50 connects to an end portion of the transmission connector 60, and can be fixed in the first fixing slot 71. On the time of folding line-type flash drive, the user can connect the connecting wire 50 to the end portion of the storage and transmission body 40 through the open slot 72, and fix the connecting wire 50 in the second fixing slot 73, thus the fold of the connecting wire 50 is fixed.

However, after the user performed the fold of the connecting wire 50 by using the wire constraint member 70, the line-type flash drive has a larger folded volume; in the other hand, when a manufacturer manufactures the line-type flash drive, they need to consider design and manufacture of the wire constraint member 70, overall manufacturing cost of the current line-type flash drive is thereby increased.

At the same time, there is another line-type flash drive in current market. Please refer to FIG. 6. A storage and transmission body 40A has a receiving slot 41 formed in central top surface thereof along length direction; a connecting wire 50A electrically connected to the storage and transmission body 40A; a part of the connecting wire 50A fixed in an end of the receiving slot 41; and a transmission connector 60A disposed at an end portion of the connecting wire 50A. The transmission connector 60A and remaining part of the connecting wire 50A are movably received in another end of the receiving slot 41. Therefore, during use of this line-type flash drive, a user needs to pull up the transmission connector 60A from the receiving slot 41 to connect to the electronic product.

However, due to the part of the connecting wire 50A fixed in the receiving slot 41, the connecting wire 50A cannot be fully expanded in data transmitting process, that restrains operation freedom and connection angle of the transmission connector 60A connecting to the electronic product, inconvenience is thus caused when the user uses this line-type flash drive.

### SUMMARY OF THE INVENTION

An aspect of the present invention is to improve the drawbacks in current technology that the line-type flash drives have the larger folded volume and the overall increased manufacturing cost due to the use of wire constraint member, or have the restrained operation freedom and connection angle of the transmission connector due to a part of connecting wire fixed in the storage and transmission body. With implementation of technical means of the present invention, an electronic storage and transmission device has a smaller folded volume that facilitates to receive the device and to reduce the manufacturing cost of the electronic storage and transmission device.

In order to achieve the aforesaid aspect, the technical means utilized in the present invention is to design an electronic storage and transmission device, which includes a storage and transmission body, a holding base, a connecting wire and a transmission connector; wherein the holding base is located at an end portion of the transmission device body, and sticks out a top surface of the storage and transmission body; an end portion of the connecting wire is fixed on the holding base, and electrically connects to the storage and transmission body; an end portion of the transmission connector electrically connects to another end of the connecting wire; and the holding base has a receiving slot, transmission connector can be fixed in the receiving slot through a side of the holding base.

In the electronic storage and transmission device, the holding base is a soft material.

In the electronic storage and transmission device, the holding base further has a fixing portion and an accommodating portion; the fixing portion is formed on the top portion of the holding base, the accommodating portion is formed between the top portion of the holding base and the top surface of the storage and transmission body; when the transmission connector abuts the accommodating portion, the fixing portion can stop the transmission connector detach from the receiving slot.

In the electronic storage and transmission device, the storage and transmission body is a flash drive, and further has a body connection port, and the body connection port electrically connects to another end portion of the storage and transmission body.

In the electronic storage and transmission device, a specification of the body connection port of the storage and transmission body is universal serial bus.

In the electronic storage and transmission device, the transmission connector further has a transmission connection port, and the transmission connection port electrically connects to another end portion of the transmission connector.

In the electronic storage and transmission device, a specification of the transmission connection port of the transmission connector is universal serial bus.

In the electronic storage and transmission device, the storage and transmission body and the holding base are formed in monolithic piece.

Advantages of the present invention are that the connecting wire is fixed on the holding base only with the end portion, the connecting wire can be fully expanded during data transmitting process, so as to allow the transmission connector connect to the electronic product at a position far away from the holding base, a user can operate the device of present invention in freedom, and thus the restrained connection angle in current technology is improved; moreover, by disposing the holding base on an end portion of the storage and transmission body, the transmission connector can be directly fixed in the holding base, it facilitates user to receive the connecting wire, due to change in width of receiving slot of the holding base, when the transmission connector abuts the accommodating portion, the fixing portion can stop the transmission connector detach from the receiving slot, so that the transmission connector can be directly received and fixed in the holding base, to reduce the folded volume of the electronic storage and transmission device of the present invention, and further to reduce the manufacture and installation of wire fixing component to decrease the manufacturing cost of the electronic storage and transmission device; additionally, the device of the present invention includes the storage and transmission body, the connecting wire and transmission connector, the storage and transmission body is a flash drive, the connecting wire and the transmission connector are regarded as electrical transmission interface, and thus the device of the present invention simultaneously have functions of data storage and charging electronic products.

### BRIEF DESCRIPTION OF THE DRAWINGS

FIG. 1 is a perspective view illustrating an expanded embodiment of the present invention;

FIG. 2 is a perspective view illustrating a folded embodiment of the present invention;

FIG. 3 is a front view illustrating an electronic storage and transmission device of the present invention;

FIG. 4 is a perspective view illustrating a storage and transmission body of the present invention;

FIG. 5 is a perspective view illustrating a device of current technology; and

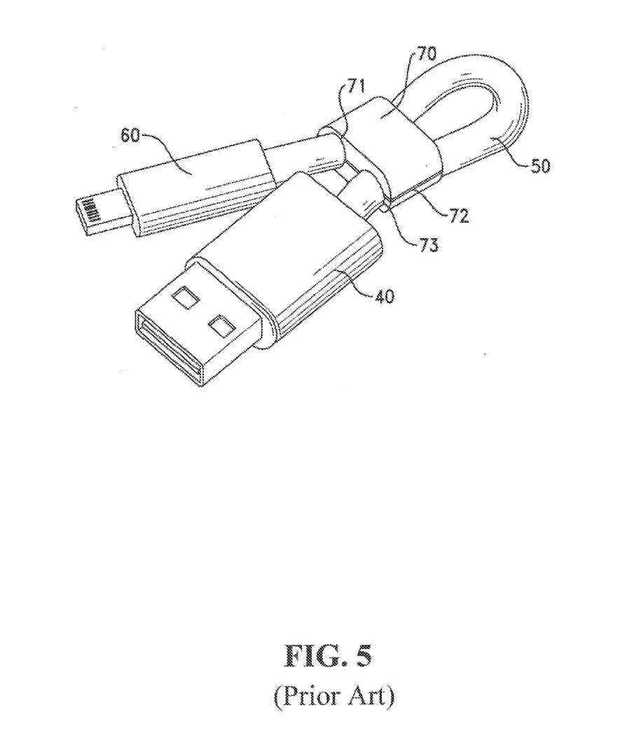

FIG. 6 is a side view illustrating another device of current technology.

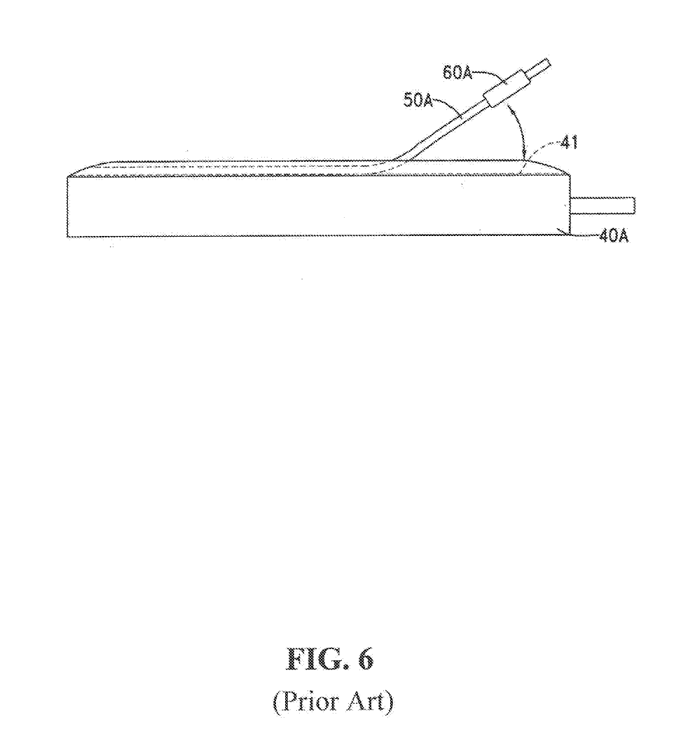

### DETAILED DESCRIPTION OF PREFERRED EMBODIMENTS

The technical means employed by the present invention to achieve the aforesaid aspect will be further elaborated with accompanying drawings and preferred embodiments as follows.

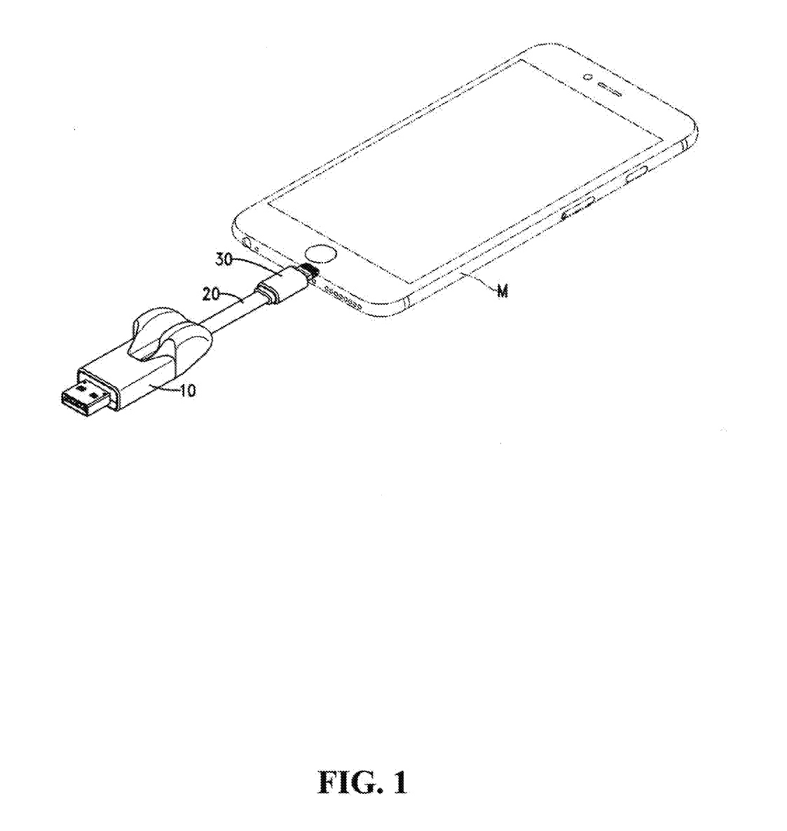

Please refer to FIG. 1. An electronic storage and transmission device of the present invention includes a storage and transmission body 10, a holding base 11, a connecting wire 20 and a transmission connector 30.

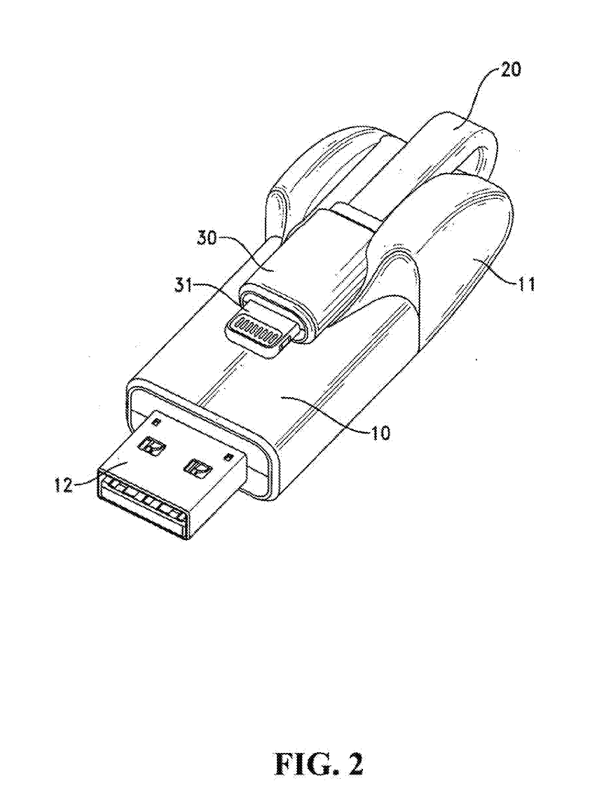

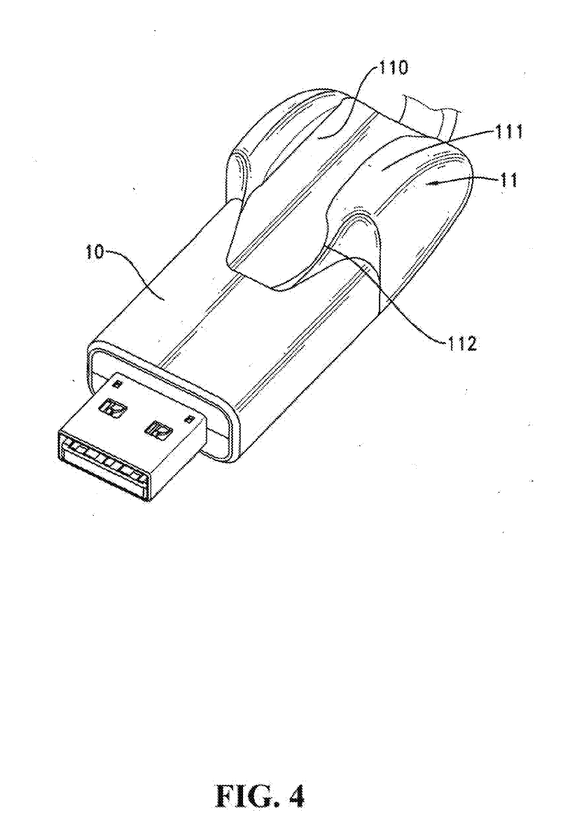

Please refer to FIGS. 2-4. The storage and transmission body 10 has a body connection port 12; specifically, the storage and transmission body 10 is a flash drive.

The holding base 11 is located at an end portion of the transmission device body 10, and sticks out a top surface of the storage and transmission body 10, the holding base 11 has a receiving slot 110, a fixing portion 111 and an accommodating portion 112; specifically, the holding base 11 is a soft material, such as rubber. In an embodiment, the storage and transmission body 10 and the holding base 11 can be formed in monolithic piece.

The receiving slot 110 formed in the holding base 11 is towards the top surface of the storage and transmission body 10 from a top portion of the holding base 11, and a width of the receiving slot 110 located at the top portion of the holding base 11 is smaller than a width of the receiving slot 110 located at the top surface of the storage and transmission body 10.

The fixing portion 111 is formed on the top portion of the holding base 11, and corresponds to the receiving slot 110 located at the top portion of the holding base 11 in position.

The accommodating portion 112 is formed on the holding base 11 adjacent to the top surface of the storage and transmission body 10, and corresponds to the receiving slot located 110 at the top surface of the storage and transmission body 10 in position. In other words, the accommodating portion 112 is formed between the top portion of the holding base 11 and the top surface of the storage and transmission body 10.

A specification of the body connection port 12 is universal serial bus (USB), and the body connection port 12 electrically connects to another end portion of the storage and transmission body 10.

Please refer to FIG. 2. An end portion of the connecting wire 20 is fixed on the holding base 11, and electrically connects to the storage and transmission body 10.

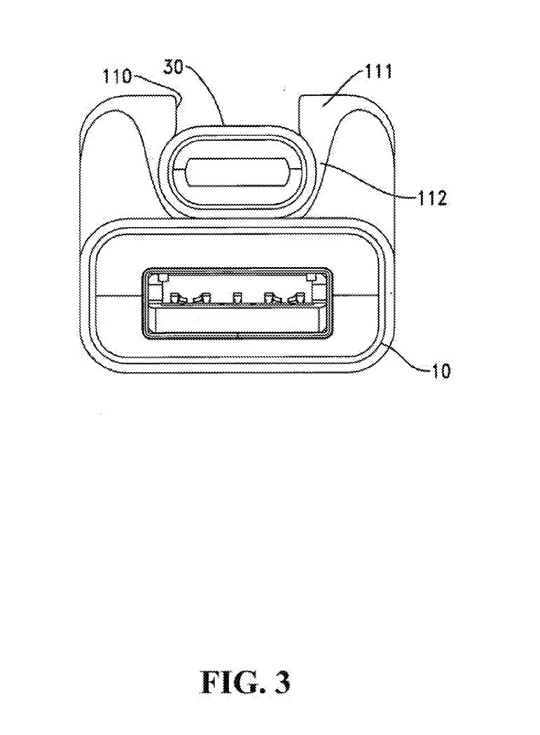

Please refer to FIGS. 2-3. The transmission connector 30 has a transmission connection port 31, an end portion of the transmission connector 30 electrically connects to another end of the connecting wire 20, the transmission connector 30 can be fixed in the holding base 11; specifically, the transmission connector 30 can pass through a side of the holding base 11 to be fixed in the receiving slot 110 located at the top surface of the storage and transmission body 10; that is, when the transmission connector 30 abuts the accommodating portion 112 of the holding base 11, the fixing portion 111 stops the transmission connector 30 detach from the receiving slot 110.

The transmission connection port 31 electrically connects to another end portion of the transmission connector 30, and a specification of the transmission connection port 31 is universal serial bus (USB).

In the present invention, due the connecting wire 20 is fixed on the holding base 11 only with the end portion, the connecting wire 20 can be fully expanded during data transmission, so as to allow the transmission connector 30 connect to a mobile device M, as shown in FIG. 1, at a position far away from the holding base 11, a user can operate the device of present invention in freedom, and thus the restrained connection angle in current technology is improved.

Moreover, by disposing the holding base 11 on an end portion of the storage and transmission body 10, the transmission connector 30 can be directly fixed in the holding base 11, when the electronic storage and transmission device of the present invention is going to be folded, it facilitates user to receive the connecting wire 20; due to change in width of receiving slot 110 of the holding base 11, when the transmission connector 30 abuts the accommodating portion 112, the fixing portion 111 can stop the transmission connector 30 detach from the receiving slot 110, so that the transmission connector 30 can be directly received and fixed in the holding base 11, not only to reduce the folded volume of the electronic storage and transmission device of the present invention, but also to reduce the manufacture and installation of wire fixing component, further to decrease the manufacturing cost of the electronic storage and transmission device.

Additionally, the device of the present invention includes the storage and transmission body 10, the connecting wire 20 and transmission connector 30; specifically, the storage and transmission body 10 is a flash drive, the connecting wire 20 and the transmission connector 30 are regarded as electrical transmission interface, and thus the device of the present invention simultaneously have functions of data storage and charging electronic products; that is, when the storage and transmission body 10 is inserted into a desktop computer or a notebook computer, the connecting wire 20 and the transmission connector 30 can be used as an electrical connecting wire to charge the mobile device M.

The above description is only for the embodiment of the present invention, but not limit the patent scope of the present invention, any modifications and arrangements by utilizing the technical programs and ideas of the present invention, directly or indirectly applied to relative technical fields, the scope of the appended claims of the present invention should encompass all such modifications and arrangements.

What is claimed is:

1. An electronic storage and transmission device, comprising: a storage and transmission body, a holding base, a connecting wire and a transmission connector;
wherein the holding base is located at an end portion of the transmission device body, and sticks out a top surface of the storage and transmission body;
an end portion of the connecting wire is fixed on the holding base, and electrically connects to the storage and transmission body;
an end portion of the transmission connector electrically connects to another end of the connecting wire; and
the holding base has a receiving slot, the transmission connector can be fixed in the receiving slot through a side of the holding base.

2. The electronic storage and transmission device according to claim 1, wherein the holding base is a soft material.

3. The electronic storage and transmission device according to claim 1, wherein the holding base further has a fixing portion and an accommodating portion;
the fixing portion is formed on the top portion of the holding base, the accommodating portion is formed between the top portion of the holding base and the top surface of the storage and transmission body;
when the transmission connector abuts the accommodating portion, the fixing portion can stop the transmission connector detach from the receiving slot.

4. The electronic storage and transmission device according to claim 3, wherein the storage and transmission body is a flash drive, and further has a body connection port, and the body connection port electrically connects to another end portion of the storage and transmission body.

5. The electronic storage and transmission device according to claim 4, wherein a specification of the body connection port of the storage and transmission body is universal serial bus.

6. The electronic storage and transmission device according to claim 4, wherein the transmission connector further has a transmission connection port, and the transmission connection port electrically connects to another end portion of the transmission connector.

7. The electronic storage and transmission device according to claim 6, wherein a specification of the transmission connection port of the transmission connector is universal serial bus.

8. The electronic storage and transmission device according to claim 1, wherein the storage and transmission body and the holding base are formed in monolithic piece.
